(19) United States
(12) Patent Application Publication
(10) Pub. No.: US 2012/0238059 A1
(43) Pub. Date: Sep. 20, 2012

(54) SACRIFICIAL SUBSTRATE FILM FOR BALL LAND PROTECTION

(75) Inventors: NORBERT JOSON SANTOS, BAGUIO-CITY (PH); EDGAR DOROTAYO BALIDOY, BENGUET (PH); MARLON CARINO CALPOTURA, PANGASINAN (PH); ARVIN ABELLERA DELA CRUZ, BAGUIO-CITY (PH); LESLIE BAHINGAWAN KIM, BAGUIO-CITY (PH)

(73) Assignee: TEXAS INSTRUMENTS INCORPORATED, Dallas, TX (US)

(21) Appl. No.: 13/050,638

(22) Filed: Mar. 17, 2011

(51) Int. Cl. H01L 21/56

(52) U.S. Cl. 438/118; 438/124; 257/E21.502

(57) ABSTRACT

A method of forming solder balls on package substrates includes attaching a semiconductor die to a frontside of a package substrate that includes a film over a bottomside of the package substrate including over a plurality of ball land areas configured to receive solder balls thereon, followed by forming an encapsulating mold layer over the semiconductor die. The film blocks contamination such as mold debris from reaching the ball land areas during die attachment and molding. The film is then removed from the bottomside of the package substrate after molding to expose the plurality of exposed ball land areas. Solder balls are dispensed onto the plurality of exposed ball land areas.

### FIELD

Disclosed embodiments relate to integrated circuit (IC) devices including ball grid array packages.

### BACKGROUND

A ball grid array (BGA) semiconductor package has a high number of input/output pins along with a high mounting density. BGA semiconductor packages include solder balls which are fused on one surface of the semiconductor package. The solder balls serve as input/output (I/O) terminals for the device.

The BGA semiconductor package includes a semiconductor chip which is centrally bonded to the topside surface of a substrate, such as a laminate substrate made of bismaleimide triazine epoxy resin by an epoxy layer. The semiconductor chip has I/O pads connected to metal traces formed on the outer portion of the topside surface of the substrate by wires. A solder mask layer is formed on the metal traces to protect a circuit pattern configured by the metal traces. Such metal traces and the solder mask layer are also laminated on the bottomside of the substrate. A plurality of land metal elements are formed on the bottomside of the substrate. The land metal elements are connected to the metal traces, respectively. Solder balls are fused onto the land metal elements, respectively. In order to protect the semiconductor chip and wires from the environment, a seal is molded on the topside surface of the substrate. Thus, a one-side molding structure is obtained for the BGA semiconductor package.

### SUMMARY

Disclosed embodiments address the problem of assembly yield loss due to debris or foreign material (referred to herein collectively as “contamination”) deposited on the ball land areas before solder ball attach causing solder ball-based rejects. Such embodiments are based on the recognition that contamination such as mold debris can be deposited on over the ball land pad areas on the bottomside surface of the package substrate during frontside processing (e.g., die attach and mold processing) prior to the ball attach process. The contamination has been found to comprise mainly burnt fiber, epoxy materials and/or melted plastic. Such contamination cannot be simply blown off from out of the ball lands, such as with an air or nitrogen gun, likely due to high temperature frontside assembly processing (e.g. 180° C.) that acts to secure the contamination to the ball land areas.

Including a disclosed film that covers all the ball land areas on the bottomside of the package substrate before frontside assembly processing has been found to largely eliminate ball rejects due to contamination that would otherwise be added to the ball land areas during the frontside assembly steps. One disclosed embodiment comprises a method of forming solder balls on package substrates. A film attached over a bottomside of a package substrate having a plurality of ball land areas is removed, where the package substrate includes a semiconductor die attached to its frontside. The removal of the film provides a plurality of exposed ball land areas. Since the film is removed before the ball attach process, it is thus a sacrificial film. Solder balls are then dispended onto the plurality of exposed ball land areas.

Another disclosed embodiment attaches a film over the ball land areas on the bottomside of the package substrate to protect the ball land areas from contamination that would otherwise be deposited during frontside assembly processing prior to the ball attach process. In another embodiment the film is provided on the bottomside of the package substrate by the package substrate vendor. A die attach step attaches a semiconductor die to a frontside of the package substrate. An encapsulating mold layer is then formed over the semiconductor die. The film is removed from the bottomside of the package substrate after molding to expose the plurality of exposed ball land areas, and solder balls are dispensed onto the plurality of exposed ball land areas.

### BRIEF DESCRIPTION OF THE DRAWINGS

FIG. 1A is a depiction showing a film having an adhesive on opposing sides sized to fit over and be attached to the bottomside of a package substrate that includes a plurality of ball land areas configured to receive solder balls thereon, according to an example embodiment.

FIG. 1B is a depiction showing the film in FIG. 1A attached to the bottomside of the package substrate shown in FIG. 1A, according to an example embodiment.

FIG. 2A is a flow chart that shows steps in an example method of forming solder balls on package substrates, according to example embodiment.

FIG. 2B is a flow chart that shows steps in another example method of forming solder balls on package substrates, according to example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

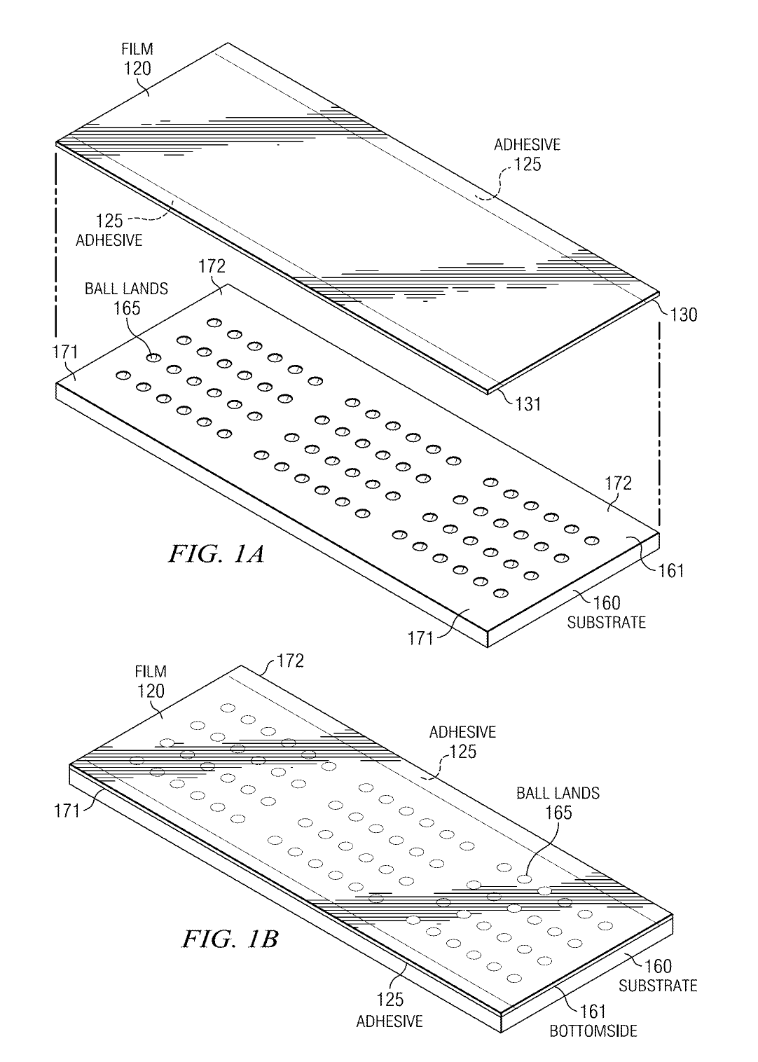

FIG. 1A is a depiction showing a film 120 having an adhesive 125 on opposing sides 130 and 131 of the film sized to fit over and be attached to the bottomside 161 of a package substrate 160 that includes a plurality of ball land areas 165 configured to receive solder balls thereon, according to an example embodiment. Although not shown, a patterned solder mask layer or other patterned dielectric layer may define the ball land areas 165. In one embodiment the ball land areas 165 include circularly shaped gold pads. However, the ball land areas 165 can have other shapes and can be formed from other electrically conductive materials.

Package substrate 160 includes side portions that are located beyond the ball land areas 165 referred to herein as side rails 171 and 172. Package substrate 160 can comprise a variety of substrates such as a single or multilayer organic or ceramic substrate, and is generally provided as a substrate sheet comprising a plurality of interconnected of package substrates.

The adhesive 125 shown on sides 130 and 131 of the film 120 align with the side rails 171 and 172 of package substrate 160 so that after placement of the film 120 on package substrate 160 the adhesive 125 is on the side rails 171 and 172, but not on ball land areas 165. Although an adhesive 125 is described for securing the film 120 to the bottomside 161 of the package substrate 160, other attachment arrangements that facilitate removal of the film 120 after frontside assembly processing may be used. For example, mechanical fasteners such as clips may be used.

FIG. 1B is a depiction showing the film 120 attached to the bottomside 161 of the package substrate 160, according to an example embodiment. As described below, after attachment of the film 120 to the package substrate 160, the film 120 over the bottomside 161 of the package substrate 160 protects the ball lands areas 165 from contamination such as mold debris from being deposited during frontside assembly processing, such as during die attaching a semiconductor die to a frontside of the package substrate 160, and forming an encapsulating mold layer over the attached semiconductor die. The semiconductor die may be attached face up or face down (e.g. flip chip). The film 120 is then removed from the bottomside 161 of the package substrate 160 after molding to provide a plurality of exposed ball land areas 165, followed by ball attach processing comprising dispensing solder balls onto the plurality of exposed ball land areas.

Since the die attach and mold processing both generally involve temperatures of at least 150° C., the film 120, and the material for attachment of the film 120, such as the adhesive 125, generally both comprise materials that are tolerant to a temperature of at least 200° C. For example, the film 120 can comprise comprises a suitable high temperature polymer, such as based on an ethylene-tetrafluoroethylene copolymer (ETFE) which is a thermoplastic fluoropolymer, such as FLUON®ETFE (AGC Chemicals Europe, Ltd). The film 120 may also comprise a ceramic. A typical thickness for the film 120 is 30 to 50 μm.

When the structure for attachment of the film 120 comprises an adhesive 125, the adhesive can comprise a high temperature glue, such as PERMABOND820™ which comprises a modified ethyl cyanoacrylate, provided by Permabond Engineering Adhesives (Somerset, N.J.). Another example high temperature tolerant adhesive is 3M™ ULTRA HIGH TEMPERATURE 100HT ADHESIVE TRANSFER TAPES 9082™ and 9085™ (3M™ St. Paul, Minn.), which are acrylic-based adhesives.

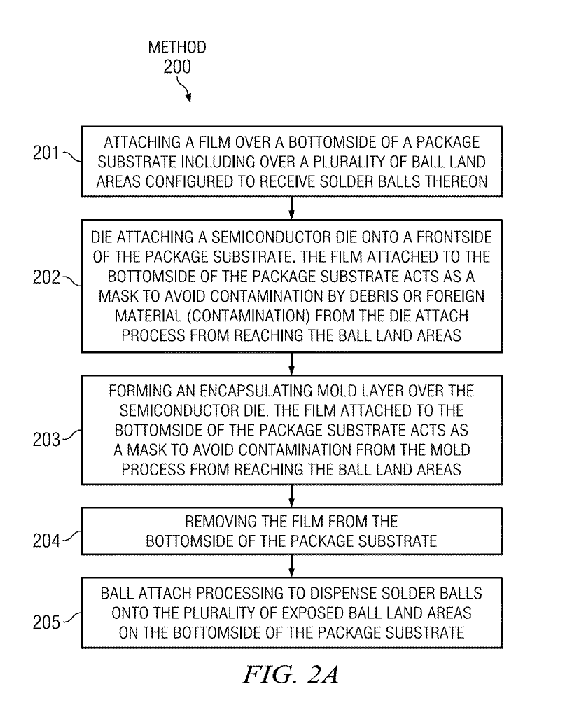

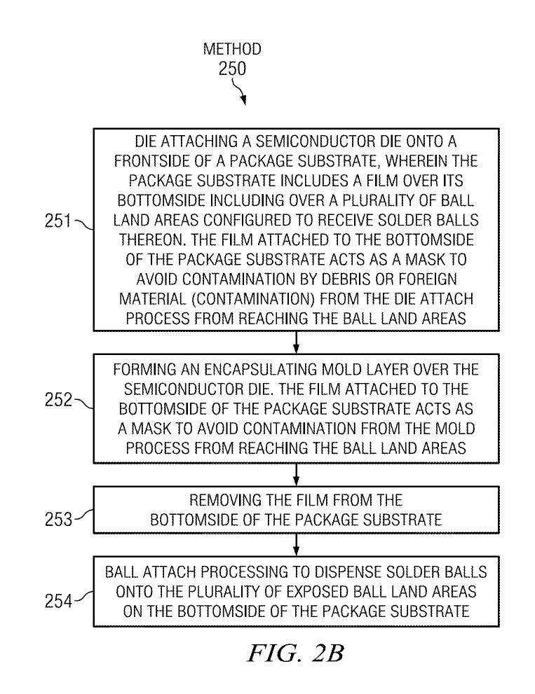

FIG. 2A is a flow chart that shows steps in an example method 200 of forming solder balls on package substrates, according to example embodiment. Step 201 comprises attaching a film 120 over a bottomside of a package substrate 160 including over a plurality of ball land areas configured to receive solder balls thereon. Step 202 comprises die attaching a semiconductor die onto a frontside of the package substrate. The film attached to the bottomside 161 of the package substrate 160 during step 202 acts as a mask to avoid contamination from the die attach process from reaching the ball land areas. In one process flow, bond pads on the semiconductor die are wire bonded to pads on the package substrate after the die attach.

Step 203 comprises forming an encapsulating mold layer over the semiconductor die. The film 120 attached to the bottomside 161 of the package substrate 160 during step 203 avoids contamination from the mold encapsulation process from reaching the land pads. The mold processing generally includes a post mold cure, which can include processing at temperatures up to about 180° C.

Step 204 comprises removing the film 120 from the bottomside of the package substrate after step 203 to expose the plurality of exposed ball land areas. In the case of an adhesive material for attaching the film to the package substrate, the removing can comprise use of an appropriate solvent that dissolves the adhesive. Some adhesives can be removed by ultraviolet light processing. Step 205 comprises a ball attach process that dispenses solder balls onto the plurality of exposed ball land areas on the bottomside of the package substrate. Since the film 120 protects the otherwise exposed ball land areas from contamination that would be deposited during die attach (step 202) and molding (step 203) prior to the ball attach process, method 200 essentially eliminates ball rejects upon post assembly inspection due to contamination on the ball land areas.

FIG. 2B is a flow chart that shows steps in an another example method 250 of forming solder balls on package substrates, according to example embodiment. This embodiment is suitable for assembly flows where the package substrate is provided by another facility such as by a substrate manufacturer to have a predetermined ball land pattern defined by a patterned solder mask layer formed on the bottomside of the substrate and a film, such as film 120, attached to the bottomside 161 of the package substrate 160. Step 201 described above relative to method 200 (attaching a film 120 over a bottomside of a package substrate 160) is not needed since the package substrate is provided (e.g., to the assembly site) having the film 120 over a bottomside of a package substrate 160. Step 251-254 are analogous to steps 202-205 described above for method 200. Step 251 comprises die attaching a semiconductor die onto a frontside of the package substrate. Step 252 comprises forming an encapsulating mold layer over the semiconductor die. Step 253 comprises removing the film 120 from the bottomside of the package substrate after step 252 to expose the plurality of exposed ball land areas. Step 254 comprises a ball attach process that dispenses solder balls onto the plurality of exposed ball land areas on the bottomside of the package substrate. Since the film 120 protects the otherwise exposed ball land areas from contamination that would be deposited during die attach and molding prior to the ball attach process, method 250 essentially eliminates ball rejects upon post assembly inspection due to contamination on the ball pads.

Disclosed embodiments can be integrated into a variety of assembly flows to form a variety of different packaged semiconductor devices and related products. The assembly can comprise single die or multiple die, such as PoP configurations comprising a plurality of stacked die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the die can formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A method of forming solder balls on package substrates, comprising:
attaching a film over a bottomside of a package substrate including over a plurality of ball land areas configured to receive solder balls thereon;
die attaching a semiconductor die onto a frontside of said package substrate;
forming an encapsulating mold layer over said semiconductor die;
removing said film from said bottomside of said package substrate after said forming to expose said plurality of exposed ball land areas, and
dispensing solder balls onto said plurality of exposed ball land areas.

2. The method of claim 1, wherein said film comprises a material that is tolerant to a temperature of at least 200° C.

3. The method of claim 1, wherein said film is attached to bottomside of said package substrate with an adhesive material on side rails of said package substrate, and wherein said adhesive material is tolerant to a temperature of at least 200° C.

4. The method of claim 3, wherein said removing said film comprises dissolving said adhesive material using a solvent for said adhesive material.

5. The method of claim 1, wherein said film comprises a polymer.

6. The method of claim 5, wherein polymer comprises ethylene tetrafluoroethylene (ETFE).

7. The method of claim 1, wherein said film comprises a ceramic.

8. A method of forming solder balls on package substrates, comprising:
removing a film attached over a bottomside of a package substrate having a plurality of ball land areas and a semiconductor die attached to its frontside, said removing providing a plurality of exposed ball land areas, and
dispensing solder balls onto said plurality of exposed ball land areas.

9. The method of claim 8, further comprising before said removing said film:
die attaching said semiconductor die onto said frontside of said package substrate, and
forming an encapsulating mold layer over said semiconductor die.

10. The method of claim 8, wherein said film comprises a material that is tolerant to a temperature of at least 200° C.

11. The method of claim 8, wherein said film is attached to bottomside of said package substrate with an adhesive material on side rails of said package substrate, and wherein said adhesive material is tolerant to a temperature of at least 200° C.

12. The method of claim 11, wherein said removing said film comprises dissolving said adhesive material using a solvent for said adhesive material.
